(19) United States
(12) Patent Application Publication
(10) Pub. No.: US 2026/0276759 A1
(43) Pub. Date: Sep. 17, 2026

(54) MAGNETOMETER COMPRISING A SENSOR CRYSTAL

(71) Applicant: Robert Bosch GmbH, Stuttgart (DE)

(72) Inventors: Timo Weggler, Ulm (DE); Andreas Brenneis, Renningen (DE); Florian Mauch, Talheim (DE)

(21) Appl. No.: 19/469,120

(22) PCT Filed: Apr. 4, 2024
(86) PCT No.: PCT/EP2024/059182

§ 371 Date: Sep. 25, 2025

(30) Foreign Application Priority Data
May 3, 2023 (DE) 10 2023 204 094.8

(51) Int. Cl. G01R 33/26; G01R 33/383

(52) U.S. Cl. CPC G01R 33/26; G01R 33/383

(57) ABSTRACT

A magnetometer for detecting a magnetic field. The magnetometer includes an excitation light source to emit an excitation beam, a sensor crystal that has a magneto-optical defect, and a device for generating a microwave field. The sensor crystal, the device, and the excitation light source are configured and disposed relative to one another such that the excitation light beam causes an emission of fluorescence radiation in the magneto-optical defect of the sensor crystal and the microwave field in the sensor crystal can be detected. The magnetometer includes a detector configured and disposed such that it detects the emitted fluorescence radiation, and at least two permanent magnets, which are disposed and designed such that they generate an at least approximately homogenous static magnetic field in the sensor crystal. The sensor crystal and the at least two permanent magnets are disposed on a common positioning element.

### FIELD

The present invention relates to a magnetometer for detecting a magnetic field and a method for operating such a magnetometer.

### BACKGROUND INFORMATION

So-called NV magnetometers are used to detect a magnetic field. These comprise a diamond, the crystal lattice of which has defects in the form of NV centers. In an NV center, a nitrogen atom occupies the lattice site of a carbon atom, and a vacancy is disposed in direct proximity to the nitrogen atom-again on the lattice site of a carbon atom. Irradiating such a crystal lattice with excitation radiation having a wavelength between 490 nm and 575 nm induces an electronic transition in the crystal lattice from a ground state ³A₂ to an excited state ³E. From the excited state ³E, the NV center relaxes back to the ground state ³A₂ with the emission of fluorescence radiation in a wavelength range between 650 nm and 750 nm. The ground state ³A₂ has three magnetic substates with mₛ=0 and mₛ=±1. The states with mₛ=0 and mₛ=±1 differ by an energy difference of 2.87 GHz (zero field splitting). The excited state ³E also has three magnetic substates with mₛ=0 and mₛ=±1. If the NV center in the ground state ³A₂ is now exposed to a microwave field with a frequency of 2.87 GHz, the NV center oscillates between the mₛ=0, ³A₂ ground state and the mₛ=±1, ³A₂ ground state. Irradiation with the excitation radiation then partially shifts the NV center from the mₛ=±1, ³A₂ ground state to the excited mₛ=±1, ³E state. From there, it relaxes back to the ground state, largely without radiation. If the amplitude of the fluorescence radiation is measured as a function of the frequency of the microwave field, there is a sudden drop in the amplitude of the fluorescence radiation (a so-called dip) at a frequency of 2.87 GHz. The reason for the drop in the amplitude of the fluorescence radiation is that, when irradiated with a microwave field having a frequency of 2.87 GHz, there are fewer NV centers in the mₛ=0, ³A₂ ground state that are available to be optically excited and that relax to the mₛ=±1, ³A₂ ground state while emitting fluorescence radiation.

In an external magnetic field, the mₛ=±1, ³A₂ ground state splits into two states with the spin quantum number mₛ=1 and mₛ=−1 (Zeemann effect). If the amplitude of the fluorescence radiation is then measured while changing the frequency of the microwave field, two dips are obtained. The frequencies at which these dips occur depend on the magnitude of the splitting of the mₛ=±1, ³A₂ ground state and thus on the field strength of the external magnetic field. This makes it possible to determine the field strength of an external magnetic field.

Such a magnetometer can also be used to determine the direction of the external magnetic field. This makes use of the fact that the NV diamond lattice comprises NV centers in four different orientations that are all at different angles to the external magnetic field and therefore split into the two states with the spin quantum number mₛ=1 and mₛ=−1 at different frequencies of the microwave field. In the presence of an external magnetic field, this then results in a spectrum with eight dips. The vector components of the external magnetic field can be calculated from the relative position of the dips. To obtain a well-resolved spectrum, measuring the direction of the external magnetic field requires the generation of an additional, ideally homogeneous, static magnetic field in the NV diamond that extends at a polar and an azimuthal angle relative to the edges of the NV diamond which is typically shaped as a cube or cuboid.

This is described in U.S. Patent Application Publication No. US 2019/0018091 A1, for example. The static magnetic field here is generated by a plurality of permanent magnets which are disposed in a Halbach configuration. The permanent magnets are held by a frame that is fastened to a base. The NV diamond is also mounted to this base. The permanent magnets are inserted in the frame along the perimeter of the frame, and the frame is aligned perpendicular to the base along its main plane.

### SUMMARY

The present invention relates to a magnetometer and a method for operating such a magnetometer. Example embodiments of the present invention are disclosed herein.

The magnetometer according to an example embodiment of the present invention includes an excitation light source, a sensor crystal, a device for generating a microwave field, a detector and at least two permanent magnets. The excitation light source is designed to emit an excitation beam. The excitation light source can be a diode laser. The excitation beam is then configured as a laser beam. The sensor crystal has at least one magneto-optical defect. The sensor crystal can comprise a crystal lattice. The crystal lattice can be the crystal lattice of a diamond that has at least one NV center as a defect; i.e., a vacancy and a nitrogen atom which is adjacent to the vacancy and occupies a lattice site of a carbon atom. The sensor crystal, the device for generating the microwave field and the excitation light source are configured and disposed relative to one another such that the excitation light beam emitted by the excitation light source causes an emission of fluorescence radiation in the at least one magneto-optical defect of the sensor crystal and the microwave field in the sensor crystal can be detected. The excitation light beam can be a laser beam with a wavelength between 490 nm and 575 nm; the fluorescence radiation can be radiation in a wavelength range between 650 nm and 750 nm.

The magnetometer further comprises a detector which is configured and disposed such that it detects the emitted fluorescence radiation. The detector can be a photodetector that is sensitive in a wavelength range between 650 nm and 750 nm.

The magnetometer further comprises at least two permanent magnets which are disposed and designed such that they generate an at least approximately homogenous static magnetic field in the sensor crystal. The magnetic field generated by the at least two permanent magnets can in principle comprise homogeneous and less homogeneous regions. It is advantageous to position the sensor crystal in the most homogeneous possible region of the magnetic field. For this purpose, the sensor crystal and the at least two permanent magnets are disposed on a common positioning element. The relative positions between the permanent magnets and the sensor crystal can thus be easily defined; for example by applying fiducial marks to the positioning element. These can then serve as reference points when assembling the individual components. The positions of the sensor crystal and the permanent magnets can thus be determined and maintained very precisely. This also makes it possible to arrange the at least two permanent magnets and the sensor crystal in a space-saving manner, so that the design of the magnetometer can be compact.

According to an example embodiment of the present invention, the detector can be disposed between the sensor crystal and the positioning element. The detector is particularly preferably fastened to the sensor crystal and/or the positioning element with the aid of an adhesive. The excitation beam is in particular coupled into the sensor crystal on a side surface of the sensor crystal opposite to the detector. The sensor crystal can be configured as a polyhedron, in particular as a cube, cuboid or truncated pyramid. Further detectors can alternatively or additionally be disposed on the same or on other side surfaces of the sensor crystal. Such an arrangement enables a particularly compact configuration and a very high sensitivity of the magnetometer.

The sensor crystal and the detector can be disposed on a common support element. The support element is disposed on the common positioning element. Such an arrangement makes it possible to easily assemble the magnetometer, because individual assemblies can be put together first and then joined to form an overall structure.

According to an example embodiment of the present invention, the at least two permanent magnets and the sensor crystal can be disposed on the positioning element such that the homogeneous static magnetic field generated by the at least two permanent magnets extends at a polar angle relative to a first edge of the sensor crystal and at an azimuthal angle relative to a second edge of the sensor crystal, wherein the polar angle is preferably between 5° and 20°. The sensor crystal is configured as diamond crystal with the crystal planes {100}, {010} and {001}. The polar angle is then defined as the angle between the normals of the {001} crystal plane and the static magnetic field. The azimuthal angle is defined as the angle between the normals of the {100} crystal plane and the projection of the magnetic field vector of the static magnetic field onto the {001} crystal plane. To obtain as well-resolved a spectrum as possible, the polar angle can be between 5° and 20°, preferably between 8° and 15°, particularly preferably 11.2°. The azimuthal angle can be between 17° and 35°, preferably 26.6° (i.e. within an angular range of approximately ±9° around 26.6°). Such an arrangement of the sensor crystal with respect to the static magnetic field, and thus with respect to the orientation and position of the permanent magnets, enables a particularly compact design of the magnetometer.

According to an example embodiment of the present invention, the positioning element can be embodied as a flat component. The permanent magnets can be designed and disposed such that the at least approximately homogeneous static magnetic field extends in or parallel to a plane of the positioning element. The edges of the sensor crystal can then be oriented at a polar and/or azimuthal angle to the plane of the positioning element. The polar angle can have a value between 5° and 20°, preferably between 8° and 15°, particularly preferably 11.2°. Such a positioning element embodied as a board or plate again enables a particularly compact design of the magnetometer.

According to an example embodiment of the present invention, the at least two permanent magnets can be disposed and aligned according to a Halbach configuration. A Halbach configuration is an arrangement of permanent magnets or permanent magnet segments along a preferred direction. The magnetization directions of adjacent permanent magnets or permanent magnet segments are tilted relative to one another along the preferred direction by an angle of 90° or an angle smaller than 90°. The preferred direction can extend along a straight line or along a circular line. If the preferred direction extends along a circular line, the permanent magnets are disposed along such an imaginary circular line. To generate as homogeneous a magnetic field as possible, the magnetization direction of adjacent permanent magnets in such a planar, ring-shaped Halbach arrangement rotates 360° once along a ring portion of 180°. An arrangement of at least four permanent magnets according to a Halbach configuration is advantageous, in which case the sensor crystal is disposed in the center of the circle. Such an arrangement makes it possible to generate a very homogeneous static magnetic field in the sensor crystal.

According to an example embodiment of the present invention, the sensor crystal and the detector can be disposed on the common support element, wherein the support element is guided through between two adjacent permanent magnets. Alternatively, recesses through which one or more permanent magnets can project through the support element can be provided in the support element. In this case, in an arrangement of four permanent magnets, for instance, three of the permanent magnets are disposed outside the support element and one of the permanent magnets is disposed in such a recess.

In such arrangements, both the positioning element and the support element can be configured as flat, planar components. The positioning element on which the permanent magnets are disposed can be positioned relative to the support element such that the plane of the support element and the plane of the positioning element are oriented with respect to one another at an angle between 5° and 20°, preferably between 8° and 15°, particularly preferably 11.2°.

Such an arrangement enables very precise positioning of the individual components with respect to one another while at the same time providing a very compact design.

According to an example embodiment of the present invention, the permanent magnets can be disposed in two layers. This requires at least four permanent magnets. A first of the two layers can be disposed in a plane below the sensor crystal and a second layer can be disposed in a plane above the sensor crystal. To position the second layer, the permanent magnets of the second layer can be attached to another receiving element, in which case the permanent magnets of the second layer are disposed between the sensor crystal and the receiving element so that the receiving element holds the permanent magnets from above. Such an arrangement makes it possible to generate a particularly homogeneous magnetic field.

According to an example embodiment of the present invention, the positioning element can comprise recesses in which the permanent magnets are disposed. The permanent magnets can be fastened in these recesses by means of an adhesive layer, for instance. The provision of recesses in the positioning element makes it possible to very precisely position the permanent magnets with respect to the sensor crystal and in relation to one another.

The positioning element can be wedge-shaped and/or stepped at least in sections. The provision of a wedge angle makes it possible to dispose the permanent magnets at different heights of the positioning element and thus easily set the angle between the magnetic field plane and the edges of the sensor crystal.

The same can be achieved with a stepped configuration of the positioning element.

The support element and/or the positioning element can be configured as a printed circuit board. This enables a simplified arrangement, in particular of the detector, on the support element and/or the positioning element.

According to an example embodiment of the present invention, the permanent magnets can be configured as cylinders, cubes or cuboids. The provision of at least one straight surface enables particularly simple manufacturing of the permanent magnets and a problem-free fastening of the permanent magnets to the positioning element.

The sensor crystal can be configured as a polyhedron with at least one angle between two adjacent surfaces that deviates from 90°. This can increase the sensitivity of the magnetometer.

The present invention also comprises a method for operating a magnetometer with the aforementioned advantages.

Further advantages and embodiments of the present invention will emerge from the description and the figures.

It goes without saying that the features mentioned above and the features yet to be explained in the following can be used not only in the respectively specified combination, but also in other combinations or alone, without departing from the scope of the present invention.

### BRIEF DESCRIPTION OF THE DRAWINGS

FIG. 1 shows a side view of a magnetometer in which a sensor crystal and two permanent magnets are disposed on a common positioning element, according to an example embodiment of the present invention.

FIG. 2 shows a plan view of the magnetometer of FIG. 1.

FIG. 3 shows a plan view of a magnetometer in which a sensor crystal is disposed on a support element and the support element and a plurality of permanent magnets are disposed on a positioning element, according to an example embodiment of the present invention.

FIG. 4 shows a possible embodiment of a magnetometer comprising a support element and a positioning element, according to the present invention.

FIG. 5 shows another possible embodiment of a magnetometer comprising a support element and a positioning element, according to the present invention.

FIG. 6 shows another possible embodiment of a magnetometer comprising a support element and a positioning element, according to an example embodiment of the present invention.

### BRIEF DESCRIPTION OF THE DRAWINGS

FIG. 1 shows a magnetometer 1 comprising a sensor crystal 4, an excitation light source 2, a detector 5, two permanent magnets 6, a device 9 for generating a microwave field and a positioning element 7. It goes without saying that the magnetometer 1 can comprise more than two permanent magnets 6. The excitation light source 2 is designed to generate an excitation light beam 3, in particular a laser beam in a wavelength range between 490 nm and 575 nm, and can be configured as a diode laser, for example. The excitation light source 2 is disposed relative to the sensor crystal 4 such that the excitation light beam 3 can be directed onto the sensor crystal 4 directly or via one or more deflecting mirrors and/or beam splitters. The sensor crystal 4 can be configured as a diamond that has defects in the form of NV centers. An NV center is understood to be a vacancy in direct proximity to a nitrogen atom that occupies a lattice site of the diamond crystal lattice. The sensor crystal 4 then emits fluorescence radiation in a wavelength range between 650 nm and 750 nm, which is acquired by the detector 5. The sensor crystal 4 is configured as a cuboid with six side surfaces. The detector 5 is disposed between the sensor crystal 4 and the positioning element 7. The excitation beam 3 is coupled in through a side surface of the sensor crystal 4 opposite to the detector. Additional detectors can be disposed on the other side surfaces of the sensor crystal 4. In this embodiment example, the device 9 for generating the microwave field is also disposed on the positioning element 7.

It is oriented and designed such that it generates a microwave field in the sensor crystal 4 in a frequency range in which the spin states of the various NV centers split energetically. The permanent magnets 6 are disposed on the positioning element 7 such that they generate a largely homogeneous static magnetic field at least in some regions. The sensor crystal 4 is disposed in a largely homogeneous region of the magnetic field. The edges of the sensor crystal are disposed at a polar and an azimuthal angle to the plane of the magnetic field. The polar angle is between 5° and 20°. A polar angle between 8° and 15°, in particular 11.2°, has proven particularly advantageous. The plane of the magnetic field extends parallel or approximately parallel to the plane of the flat positioning element 7 which is configured as a printed circuit board, for example. The sensor crystal 4 can be disposed in a recess formed in the positioning element 7. The sensor crystal 4 can alternatively also be disposed on the positioning element 7 with the aid of a wedge element, for instance. It goes without saying that the permanent magnets 6 can also be disposed at an angle to the sensor crystal 4 so that the magnetic field and the sensor crystal 4 are oriented at a polar and azimuthal angle to one another.

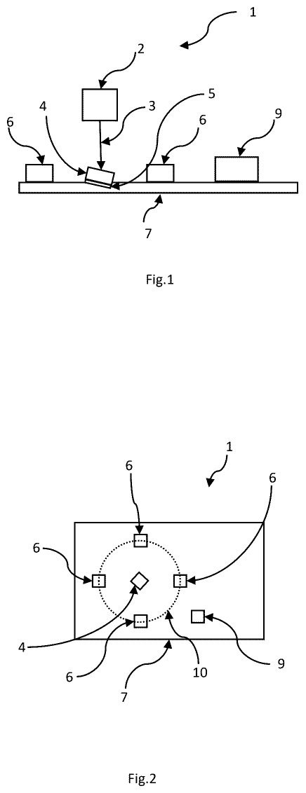

FIG. 2 shows the magnetometer 1 of FIG. 1 again in a plan view. Four permanent magnets 6 are disposed in a Halbach configuration, for example along an imaginary circular line 10. The sensor crystal 4 is disposed in the center of the circle, and thus in a largely homogeneous region of the static magnetic field.

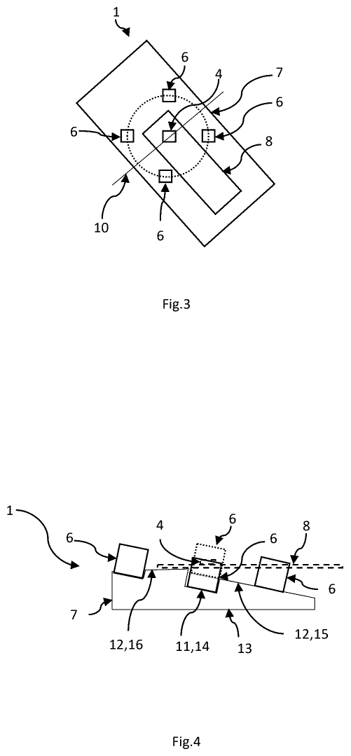

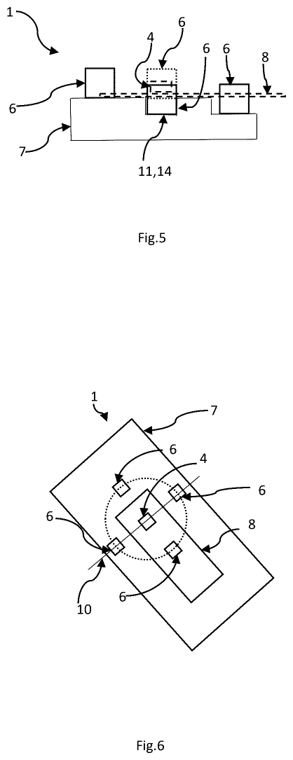

FIG. 3 shows a plan view of a magnetometer 1 that comprises a support element 8 in addition to the positioning element 7. The sensor crystal 4 is disposed on the support element 8. The detector 5 (not shown in FIG. 3) is disposed between the support element 8 and the sensor crystal 4. The permanent magnets 6 are disposed along a circular line on the positioning element 7 according to a Halbach configuration. The sensor crystal 4 is positioned at the center of the circle of the respective circle. The support element 8 is flat, e.g. configured as a printed circuit board, and is disposed between two adjacent permanent magnets 6. The support element 8 is tilted relative to an upper surface 12 of the positioning element 7 about an axis 10, wherein the axis 10 extends centrally between two permanent magnets 6 through the sensor crystal 4 and thus through the center of the circle. The support element 8 and the upper surface of the positioning element 12 form an acute angle of preferably 11.2°. Due to the orientation of the support element 8 and the positioning element 7 in relation to one another, two of the permanent magnets 6 are disposed above the plane of the support element 8 and two other permanent magnets 6 are disposed below the plane of the support element 8.

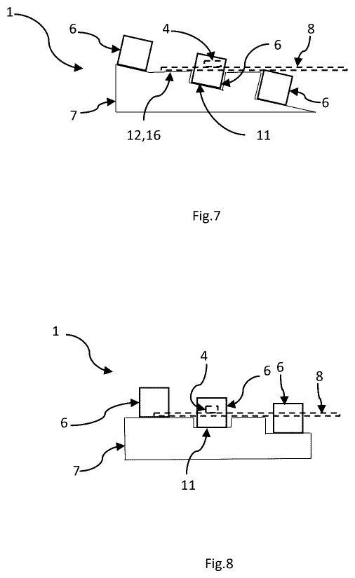

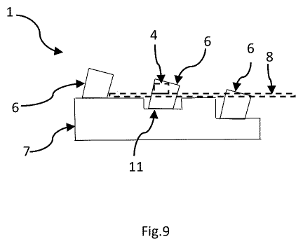

FIG. 4 and FIG. 5 both show such a magnetometer 1 in a side view. For the sake of clarity, the detector 5 is not depicted in these illustrations. FIG. 4 shows a magnetometer 1 with a partially wedge-shaped positioning element 7. On its upper surface 12, the positioning element 7 comprises subsections that are oriented parallel to the plane of the support element 8. The support element 8 is positioned on these subsections. On its upper surface 12, the positioning element 7 also comprises subsections that are disposed at a wedge angle, an acute angle of 11.2°, for example, to the support element 8 which is embodied as a flat surface. These subsections can also be configured as base surfaces 14 of recesses 11. The permanent magnets 6 are cube-, cylinder-, or cuboid-shaped and are disposed with one of their side surfaces on the subsections of the upper surface 12, in particular in the recesses 11, of the positioning element 7, which are oriented at the wedge angle to the support element 8.

FIG. 5 shows a magnetometer 1 with a stepped positioning element 7. The positioning element 7 only comprises surfaces that are oriented parallel to the plane of the support element 8. These can be configured as recesses 11, in which a part of the permanent magnets 6 is disposed. The recesses 11 can be configured such that they are at different depths in relation to the upper surface 12. Another part of the permanent magnets 6 is disposed on the upper surface 12 of the positioning element 7. The arrangement of the permanent magnets 6 at different heights produces a magnetic field that is oriented at an angle relative to the support element 8.

FIG. 6 shows a plan view of a magnetometer 1 that also comprises a support element 8 in addition to the positioning element 7. The sensor crystal is disposed on the support element 8. The detector 5 (not shown in FIG. 6) is disposed between the support element 8 and the sensor crystal 4. The permanent magnets 6 are disposed on the positioning element 7 according to a Halbach configuration. The support element 8 is flat, e.g. configured as a printed circuit board. The sensor crystal 4 is disposed centrally relative to the permanent magnets 6 disposed along a circular line. The support element 8 is tilted at an angle of 11.2° relative to the upper surface 12 of the positioning element 7 along the axis 10. Unlike the magnetometers 1 of FIGS. 3 to 5, the axis 10 extends through two of the permanent magnets 6 and through the sensor crystal 4. In this arrangement, one of the permanent magnets 6 is disposed above or in the plane of the support element and another permanent magnet 6 is disposed below the plane of the support element 8.

FIGS. 7 to 9 both show such a magnetometer 1 in a side view. For the sake of clarity, the detector 5 is again not depicted in these illustrations. FIG. 7 shows a magnetometer 1 with a partially wedge-shaped positioning element 7. On its upper surface 12, the magnetometer 1 of FIG. 7 again comprises subsections that are oriented parallel to the plane of the support element 8. The support element 8 is positioned on these subsections. The positioning element 7 likewise comprises subsections on its upper surface 12 that are disposed at a wedge angle, an acute angle of 11.2°, for example, to the support element 8 which is embodied as a flat surface. These subsections can also be configured as recesses 11. The permanent magnets 6 are cube-, cylinder-, or cuboid-shaped and are disposed with one of their side surfaces on the subsections of the upper surface 12 of the positioning element 7 which are oriented at the wedge angle to the support element 8.

The positioning element 7 of the magnetometer 1 of FIG. 8 again only comprises surfaces that are oriented parallel to the plane of the support element 8. These can be configured as recesses 11, in which a part of the permanent magnets 6 is disposed. Another part of the permanent magnets 6 is disposed on the upper surface 12 of the positioning element 7. The arrangement of the permanent magnets 6 at different heights produces a magnetic field that is oriented at an angle relative to the support element 8.

FIG. 9 shows the magnetometer 1 of FIG. 8 with the difference that the permanent magnets 6 have ground undersides. The permanent magnets 6 can alternatively or additionally also have ground upper sides. The upper sides and undersides of the cuboid, cube, or cylinder-shaped permanent magnets 6 are not oriented parallel to one another. The permanent magnets 6 are disposed at different heights. This results in an arrangement as shown in FIG. 7, except that the surfaces on which the permanent magnets 6 are disposed, for example the recesses 11, are configured parallel to the support element 8 which is embodied as a flat surface, while the upper sides of the permanent magnets 6 are oriented at a wedge angle, an acute angle of 11.2°, for example, to the support element 8 which is embodied as a flat surface.

1-15. (canceled)

16. A magnetometer for detecting a magnetic field, comprising:
an excitation light source configured to emit an excitation beam;
a sensor crystal that includes at least one magneto-optical defect;
a device configured to generate a microwave field,
wherein the sensor crystal, the device configured to generate the microwave field and the excitation light source are configured and disposed relative to one another such that the excitation light beam emitted by the excitation light source causes an emission of fluorescence radiation in the at least one magneto-optical defect of the sensor crystal, and the microwave field in the sensor crystal can be detected;
a detector which is configured and disposed such that the detector detects the emitted fluorescence radiation;
at least two permanent magnets which are disposed and configured such that the at least two permanent magnets generate an at least approximately homogenous static magnetic field in the sensor crystal,
wherein the sensor crystal and the at least two permanent magnets are disposed on a common positioning element.

17. The magnetometer according to claim 16, wherein the detector is disposed between the sensor crystal and the positioning element.

18. The magnetometer according to claim 16, wherein the sensor crystal and the detector are disposed on a common support element, and wherein the support element is disposed on the common positioning element.

19. The magnetometer according to claim 16, wherein the at least two permanent magnets and the sensor crystal are disposed on the positioning element such that the generated homogenous static magnetic field extends at a polar angle relative to a first edge of the sensor crystal and at an azimuthal angle relative to a second edge of the sensor crystal, wherein the polar angle is between 5° and 20°.

20. The magnetometer according to claim 19, wherein the positioning element is embodied as a flat component and wherein the generated at least approximately homogeneous static magnetic field extends in a plane of the positioning element.

21. The magnetometer according to claim 16, wherein the at least two permanent magnets are disposed and aligned according to a Halbach configuration.

22. The magnetometer according to claim 16, wherein the at least two permanent magnets include at least four permanent magnets which are disposed along an imaginary circular line, wherein the sensor crystal is disposed in a center of the circle.

23. The magnetometer according to claim 18, wherein the sensor crystal and the detector are disposed on the common support element, and wherein the support element is guided through between two adjacent ones of the at least two permanent magnets.

24. The magnetometer according to claim 16, wherein the at least two permanent magnets include at least four permanent magnets, wherein the at least four permanent magnets are disposed in two layers, of which one is disposed above the sensor crystal and one is disposed below the sensor crystal.

25. The magnetometer according to claim 16, wherein the positioning element includes recesses in which the at least two permanent magnets are positioned.

26. The magnetometer according to claim 16, wherein the positioning element is at least partially wedge-shaped and/or stepped.

27. The magnetometer according to claim 18, wherein the support element and/or the positioning element is embodied as a printed circuit board configured to receive the detector.

28. The magnetometer according to claim 16, wherein the at least two permanent magnets are embodied as cubes or cuboids.

29. The magnetometer according to claim 16, wherein the sensor crystal is configured as a polyhedron with at least one angle between two adjacent surfaces that deviates from 90°.

30. A method for operating a magnetometer, the method comprising:
providing the magnetometer, the magnetometer including:
an excitation light source configured to emit an excitation beam,
a sensor crystal that includes at least one magneto-optical defect,
a device configured to generate a microwave field,
wherein the sensor crystal, the device configured to generate the microwave field and the excitation light source are configured and disposed relative to one another such that the excitation light beam emitted by the excitation light source causes an emission of fluorescence radiation in the at least one magneto-optical defect of the sensor crystal, and the microwave field in the sensor crystal can be detected,
a detector which is configured and disposed such that the detector detects the emitted fluorescence radiation,
at least two permanent magnets which are disposed and configured such that the at least two permanent magnets generate an at least approximately homogenous static magnetic field in the sensor crystal,
wherein the sensor crystal and the at least two permanent magnets are disposed on a common positioning element; and
operating the magnetometer.
